(19) United States
(12) Patent Application Publication
(10) Pub. No.: US 2023/0315963 A1
(43) Pub. Date: Oct. 5, 2023

(54) METHOD OF DESIGNING AND MANUFACTURING MULTICHIP MODULE BASED ON ISOLATION SIMULATION

(71) Applicant: Skyworks Solutions, Inc., Irvine, CA (US)

(72) Inventor: Jiunn-Sheng Guo, Eastvale, CA (US)

(21) Appl. No.: 18/128,560

(22) Filed: Mar. 30, 2023

Related U.S. Application Data
(60) Provisional application No. 63/327,021, filed on Apr. 4, 2022.

(51) Int. Cl. G06F 30/367; G06F 30/3308; G06F 30/392

(52) U.S. Cl. CPC G06F 30/367; G06F 30/3308; G06F 30/392

(57) ABSTRACT

According to the present disclosure there is provided a method of generating a multichip module design, the method comprising: receiving a multichip module design, the multichip module design comprising a plurality of electrical components and a plurality of signal paths defined between the electrical components; simulating, for each electrical component and signal path, the isolation between that electrical component or signal path and a plurality of the other electrical components and signal paths; and updating the multichip module design based on the simulating. Multichip modules manufactured according to the method, and radio-frequency modules and wireless devices comprising said multichip modules are also provided.

### INCORPORATION BY REFERENCE TO ANY PRIORITY APPLICATIONS

Any and all applications, if any, for which a foreign or domestic priority claim is identified in the Application Data Sheet of the present application are hereby incorporated by reference under 37 CFR 1.57.

### BACKGROUND

### Field

Embodiments of the invention relate to methods of generating and manufacturing a multichip module design. In particular, embodiments of the invention relate to methods of generating and manufacturing a multichip module design based on simulating the isolation between electrical components.

### Description of the Related Technology

Multichip modules comprise a plurality of components and signal paths defined between these components. The components of a multichip module and the signal paths must be sufficiently isolated from one another. If two components are not sufficiently isolated then they can interfere. In the past, the isolation between two components has often only been considered once a multichip module has been made when undesired interference has been detected. Accordingly, correcting the level of isolation can require a costly redesign of the multichip module.

### SUMMARY

According to one embodiment there is provided a method of generating a multichip module design, the method comprising: receiving a multichip module design, the multichip module design comprising a plurality of electrical components and a plurality of signal paths defined between the electrical components; simulating, for each electrical component and signal path, the isolation between that electrical component or signal path and a plurality of the other electrical components and signal paths; and updating the multichip module design based on the simulating.

In some examples, the method further comprises, prior to updating the updating the multichip module design: comparing each simulated isolation to one or more predetermined isolation thresholds; and determining, based on the comparison of each simulated isolation to one or more predetermined isolation thresholds, whether the multichip module design meets one or more isolation design criteria; wherein updating the multichip design is further based on whether the multichip module design meets the one or more isolation design criteria.

In some examples, the step of receiving a multichip module design comprises generating a multichip module design.

In some examples, the step of simulating, for each electrical component and signal path, the isolation between that electrical component or signal path a plurality of the other electrical components and signal paths comprises: generating a 3D model of the multichip module design; and simulating, based on the 3D model and for each electrical component and signal path, the isolation between that component or signal path and a plurality of the other electrical components and signal paths.

In some examples, the plurality of other electrical components and signal paths includes every other electrical component and signal path of the multichip module.

In some examples, the multichip module comprises a plurality of sub-modules, each sub-module comprising one or more of the plurality of electrical components and the plurality of signal paths; and the plurality of other electrical components and signal paths includes every other electrical component and signal path in the same sub-module.

In some examples, the multichip module comprises a plurality of sub-modules, each sub-module comprising one or more of the plurality of electrical components and the plurality of signal paths; and the plurality of other electrical components and signal paths includes every other electrical component and signal path in a different sub-module.

In some examples, updating the multichip module design comprises, if it is determined that the multichip module design does not meet the one or more isolation design criteria: updating the multichip module design by adjusting at least one of the plurality of electrical components or plurality of signal paths that did not meet the isolation requirement with respect to another of the electrical components or signal paths.

In some examples, adjusting at least one of the plurality of electrical components or plurality of signal paths comprises: moving at least one of the plurality of electrical components or plurality of signal paths that did not meet the isolation requirement with respect to another of the electrical components or signal paths with respect to that other electrical component or signal path.

In some examples, the multichip module design comprises a plurality of layers, and moving at least one of the plurality of electrical components or plurality of signal paths comprises: moving the at least one of the plurality of electrical components or plurality of signal paths to a different layer.

In some examples, the multichip module design comprises a plurality of layers, and adjusting at least one of the plurality of electrical components or plurality of signal paths comprises: introducing a ground layer into the multichip module design between two of the different layers.

In some examples, adjusting at least one of the plurality of electrical components or plurality of signal paths comprises: rotating at least one of the plurality of electrical components or plurality of signal paths.

In some examples, adjusting at least one of the plurality of electrical components or plurality of signal paths comprises: moving one or more pins of the plurality of electrical components.

In some examples, each of the plurality of signal paths is represented by one or more nodes, and the isolation between a signal path and a plurality of the other electrical components and signal paths is simulated by comparing the isolation between each node of the signal path and a plurality of the other electrical components and a plurality of nodes of the other signal paths.

In some examples, the method is performed iteratively, wherein the step of receiving a multichip design module comprises receiving the updated multichip module design from the previous iteration of the method.

In some examples, the output of simulating, for each electrical component and signal path, the isolation between that electrical component or signal path and a plurality of the other electrical components and signal paths is presented in one or more of a table, a graph, and a spreadsheet.

In some examples, the method further comprises: manufacturing, if it is determined that the multichip module design does meet the one or more isolation design criteria, a multichip module in accordance with the multichip module design.

According to another aspect of the invention there is provided a multichip module manufactured according to the preceding methods.

According to another aspect of the invention there is provided a radio-frequency module comprising a multichip module manufactured according to the preceding methods.

According to another aspect of the invention there is provided a wireless device comprising a multichip module manufactured according to the preceding methods or the radio-frequency module comprising a multichip module manufactured according to the preceding methods.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic diagram of a multichip module;

FIG. 2 is a schematic diagram of a multichip module;

FIG. 3 is a method according to aspects of the present invention;

FIG. 4 is a method according to aspects of the present invention;

FIG. 5 is a schematic diagram of a two stage power amplifier;

FIGS. 6A-6D are tables of required and simulated isolation values;

FIG. 7 is a table of simulated isolation values;

FIG. 8 is a table of simulated isolation values;

FIGS. 9A-9B are tables of simulated isolation values;

FIG. 10 is a table of simulated isolation values;

FIG. 11 is a table of simulated isolation values

FIG. 12 is a table of simulated isolation values;

FIGS. 13A-13C are tables of simulated isolation values;

FIG. 14 is a table of required and simulated isolation values; and

FIG. 15 is a schematic diagram of a wireless device according to aspects of the present invention.

### DETAILED DESCRIPTION

Aspects and embodiments described herein are directed to a method for generating a multichip module design, as well as a multichip module made according to such a design and radio-frequency modules and wireless devices comprising such a multichip module. The methods herein enable multichip modules and associated devices that incorporate them to be made having suitable isolation between different components of the multichip module.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

A multichip module (MCM) is a package that comprises a number of other electronic components, such as integrated circuits, silicon dies, and so on. Typically, an multichip module comprises a substrate, which may be a printed circuit board (PCB) built on a ceramic base, with a number of integrated chips or dies disposed on the substrate. A common example of a multichip module in wireless devices is a front end module (FEM). Front end modules typically comprise amplifiers on both the transmit (Tx) and receive (Rx) paths, such as power amplifiers and low noise amplifiers respectively, a number of bandpass filters, an antenna switch module (ASM) for selecting the desired antenna, and outputs for connection to one or more antennae. It will be appreciated that this is not a complete list of components that may be present in a front end module, and other components, such as other filters and switches, may be present. Nor is it a list of required components, and in some cases listed components may be omitted.

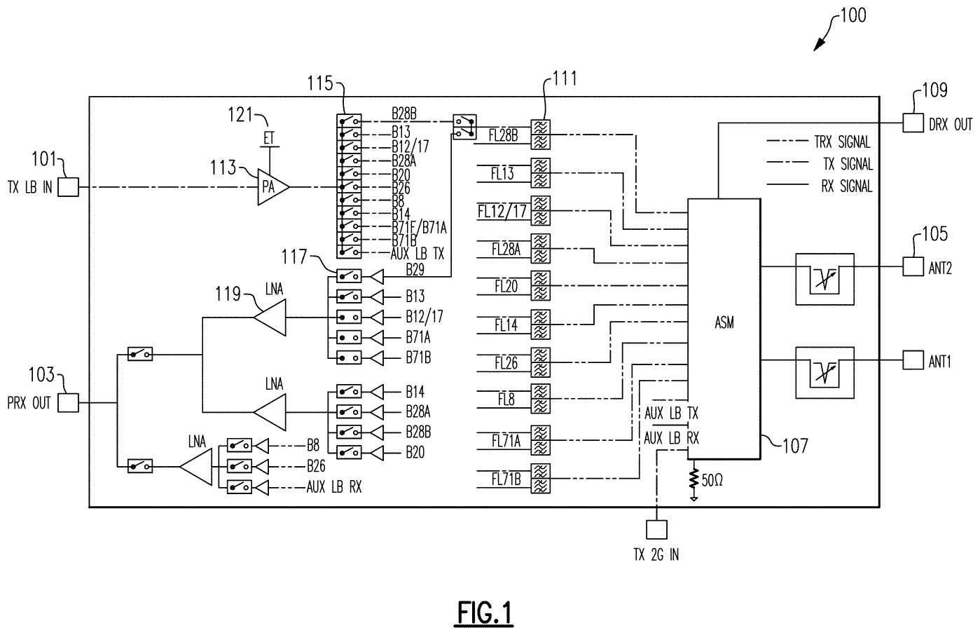

FIG. 1 illustrates a schematic diagram of a multichip module 100, which in this case is a front end module. It will be appreciated that while multichip module 100 shown in FIG. 1 is representative of some of the components and signal paths that are present on the multichip module 100 but these are arranged to give a representation of the multichip module 100 and the positioning of the components and signal paths does not necessarily correspond to the physical positions of the components and signal paths on an actual multichip module 100.

The multichip module 100 comprises a low band transmit path input 101 for receiving signals from a transceiver to be transmitted and a receive path output 103 for passing along received signals to the transceiver. The multichip module 100 also comprises two antenna connections 105, for connection two a pair of antennae, ANT1 and ANT2, and a diversity receiver connection 109. Connected to the antenna connections 105 and diversity receiver connection 109 is an antenna switch module 107.

Also connected to the antenna switch module 107 are a plurality of bandpass filters 111 defining the different radio-frequency bands that the front end module operates with. As can be seen, multichip module comprises ten bandpass filters 111 and so can transmit and receive signals in these ten bands. For example, the top bandpass filter 111 corresponds to band fourth generation (4G) long term evolution (LTE) band B28, having uplink frequencies of 703 MHz to 748 MHz and downlink frequencies of 758 MH to 803 MHz.

On the transmit path, from the low band transmit path input 101 a signal passes through power amplifier 113, which receives input from envelope tracking circuit 121, before switches 115 route the signal through the correct bandpass filter 111. The bandpass filter 111 filters out out-of-band (OOB) noise before the signal is passed to the desired antenna 105 by the antenna switch module 107. On the receive path, a received signal at the antenna switch module 107 is sent to the appropriate bandpass filter 111 to filter out received out-of-band noise. The signal then passes through amplifiers and switches 117, including low noise amplifier 119, before being output from the receive path output 103.

It will be appreciated that the multichip module 100 comprises a large number of components and signal paths for each of those components, but that only selected signal paths have been included in FIG. 1 for clarity. In particular, the signal path corresponding to band B28B on the transmit path and B29 (a supplemental downlink band within the frequencies of band B28). The portions of the signal path that are on the transmit path only are represented by the line with a single narrow dash in between long dashes, the portions of the signal path that are on the receive path only are represented by a solid line, and the portions of the signal path that are used by both the transmit and receive paths (TRX) are represented by a line with two narrow dashes between long dashes.

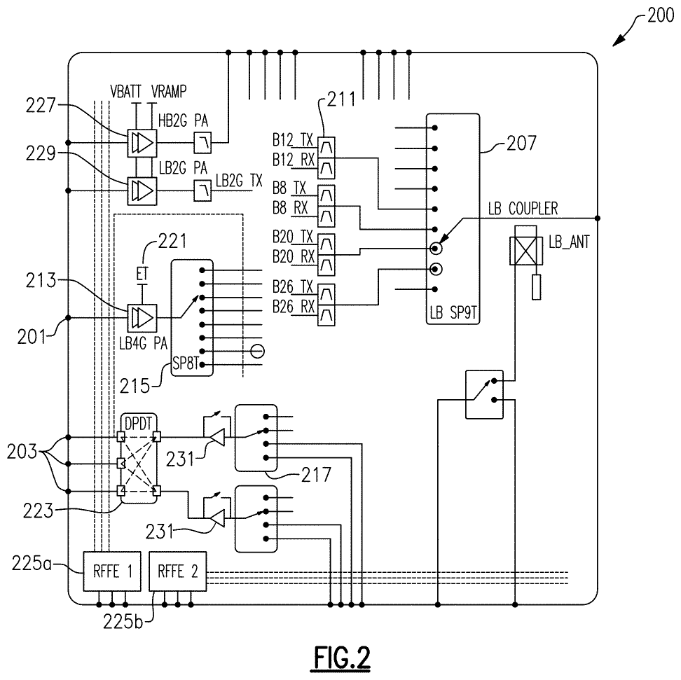

FIG. 2 illustrates another schematic representation of a multichip module 200. Whereas FIG. 1 represents the layout of components and signal paths in a way that more clearly illustrates the different components and signal paths of multichip module 100, FIG. 2 illustrates multichip module 200 in a way that more closely reflects the physical layout of the components and signal paths of multichip module 200 (though it is not necessarily a completely physically accurate representation).

Multichip module 200 comprises a 4G transmit path input 201 where a 4G radio-frequency signal to be transmitted is received by the multichip module 200, and subsequently passed to the low band 4G power amplifier 213, which can apply envelope tracking based on envelope tracking circuit 221. The correct band is then selected by switch 215, which in this case is a single pole, eight throw switch, and the transmit signal then passes through the appropriate band pass filter 211 before entering the antenna switch module 207, which directs the signal to the appropriate antenna. On the receive path, after a signal is received by the receiver and passed to antenna switch module 207, it is again passed through bandpass filters 211 before switches 217 and then throw low noise amplifiers 231. The signal then passes through dual pole double throw switch 223 before the signal is output from one of the three outputs 203.

The various switches and other components of the multichip module are controlled by a pair of radio-frequency front end controllers 225. One of these controllers 225a may control the 4G components of the multichip module, such as low band 4G power amplifier 213, and the 2G components, such as high band 2G power amplifier 227 and low band 2G amplifier 229. The other controller 225b may control the low noise amplifiers. It will be appreciated that whilst the description above has been predominantly in relation to the 4G signal pathways of multichip module 200, the multichip module 200 also comprises 2G signal pathways and the associated components, such as high band 2G power amplifier 227 and low band 2G amplifier 229 as mentioned above.

As with FIG. 1, FIG. 2 illustrates a selection of components of multichip module 200, and in practice multichip module 200 may have additional, not shown, components, or may omit some components that are illustrated. For example, if no 2G functionality is desired, then the 2G components, such as high band 2G power amplifier 227 and low band 2G amplifier 229, can be omitted. Similarly, the signal pathways between the components have not been shown in full so as not to obscure the illustration.

From considering FIGS. 1 and 2, it will be appreciated that multichip modules are highly complex with numerous components and signal pathways that often must necessarily cross or be placed nearby to one another. This can present a problem as components and signal pathways also require a certain level of isolation from one another, else different signals can interfere leading to errors and losses. Different components and signal paths have different isolation requirements, which are often specified prior to a multichip module's design and manufacture.

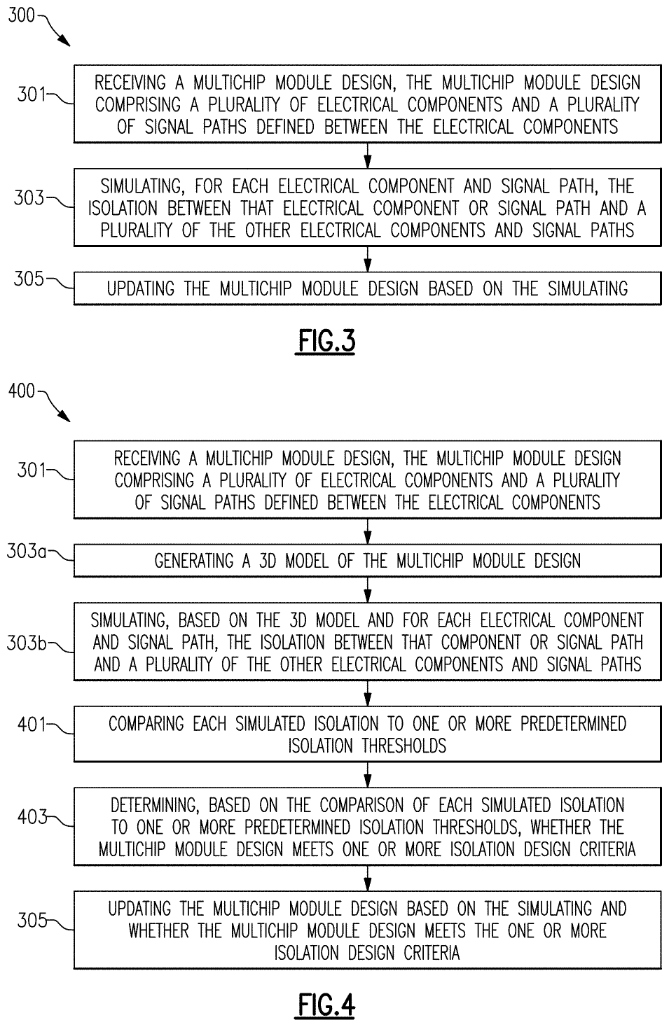

FIG. 3 illustrates a method 300 of generating a multichip module design to prevent, minimize or reduce interference and increase or maximize the isolation between the components and signal paths of a multichip module. The method begins at step 301 by receiving a multichip module design. The multichip module design comprises a plurality of electrical components and a plurality of signal paths defined between the electrical components, and it defines the layout of the multichip module. The received design may be a pre-existing design, for example from a database of existing multichip module designs, or it may be a new design that has recently been devised. As will be further discussed later, the method 300 may be iterative, and so the received design may be the design that is output from a previous iteration of method 300.

The next step, step 303, comprises simulating, for each electrical component and signal path, the isolation between that electrical component or signal path and a plurality of the other electrical components and signal paths. Each component or signal path may, for example, have the isolation between that component and every other component and signal path of the multichip module simulated. In other cases, only the isolation between the component and a subset of the other components and signal paths may be simulated. For example, the multichip module may comprise a plurality of sub-modules (e.g., an antenna switch module), and each sub-module may comprise one or more of the plurality of electrical components and the plurality of signal paths of the multichip module (e.g., the antenna switch module may comprise a plurality of switch components). In this case, the plurality of other electrical components and signal paths for which the isolation is simulated includes (and may be limited to) every other electrical component and signal path in a different sub-module. The different sub-module may be one or more specific different sub-modules, or may be every other sub-module. Alternatively, the plurality of other electrical components and signal paths may include (and may be limited to) every other electrical component and signal path in the same sub-module. In some cases, the isolation may only be calculated between certain types of components and signal paths, between components and signal paths within a certain distance, on the same or adjacent layers of the multichip module, and so on. It will be appreciated that any selection of the above criteria may be used to determine between which components and signal paths the isolation is simulated.

Finally, at step 305, the multichip module design is updated based upon the simulations performed at step 303. Preferably, the multichip module design is updated by adjusting a component or signal path that does not meet an isolation requirement with respect another component or signal path. For example, the position or orientation of a component or signal path may be adjusted, or, if the multichip module comprises multiple layers, the component or signal path may be moved to a different layer. Generally, the component or signal path will be moved further away from the component or signal path from which it is not sufficiently isolated. In some cases, it will be appreciated that additional components or signal paths may need to be adjusted as well to accommodate the adjustment to the component or signal path that is insufficiently isolated. In some cases, updating the multichip module may not comprise adjusting the components or signal paths themselves, per se, but may involve an adjustment of the multichip module. For example, an additional isolating layer, such as a ground layer, may be introduced to the multichip module design. Alternatively, or in addition, one or more pins of the plurality of electrical components or of the multichip module may be moved.

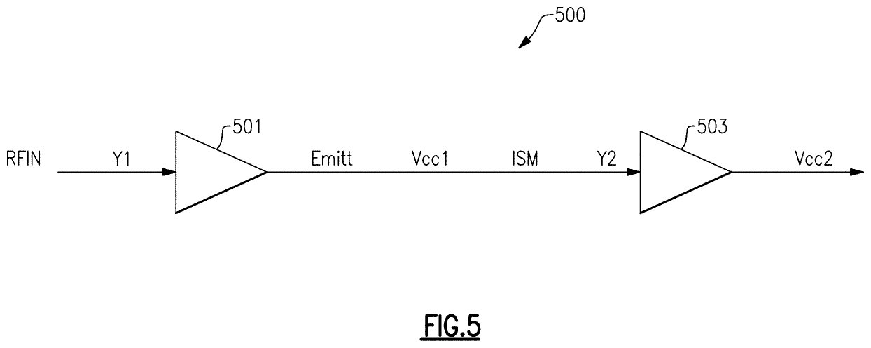

FIG. 4 illustrates another method 400, which incorporates a number of the steps of method 300 of FIG. 3. The discussion above in relation to FIG. 3 will be appreciated as being equally applicable to the method 400 of FIG. 4, and is not repeated here. Instead, only the differences between methods 300 and 400 are discussed in detail.

When comparing method 400 to method 300, the step 303 of simulating, for each electrical component and signal path, the isolation between that electrical component or signal path and a plurality of the other electrical components and signal paths is broken down into two steps, step 303a and step 303b. Step 303a comprises generating a 3D model of the multichip module design, which may be performed according to known techniques and methods, and then step 303b comprises simulating, based on the 3D model and for each electrical component and signal path, the isolation between that component or signal path and a plurality of the other electrical components and signal paths. Simulating using a 3D model of the multichip module can enable an accurate simulation of the isolation between components and signal paths to be performed, and can take into account a variety of effects including the spatial positioning of components and signal paths, the materials used in the multichip module design, and so on.

Additionally, after steps 303a and 303b but prior to step 305 of updating the multichip module design, method 400 additionally comprises steps 401 and 403. Step 401 comprises comparing each simulated isolation to one or more predetermined isolation thresholds whilst step 403 comprises determining, based on the comparison of each simulated isolation to one or more predetermined isolation thresholds, whether the multichip module design meets one or more isolation design criteria. Checking the multichip module design against isolation design criteria ensures that the multichip module with function as desired and can enable any potential issues that may arise due to insufficient isolation between components and signal paths to be overcome at the design stage prior to manufacturing of the chip. This can prevent the costs associated with setting up a manufacturing process for a new multichip module and then subsequently having to change that manufacturing process if it is later discovered that the multichip module requires alteration due to insufficient isolation between two or more components or signal paths.

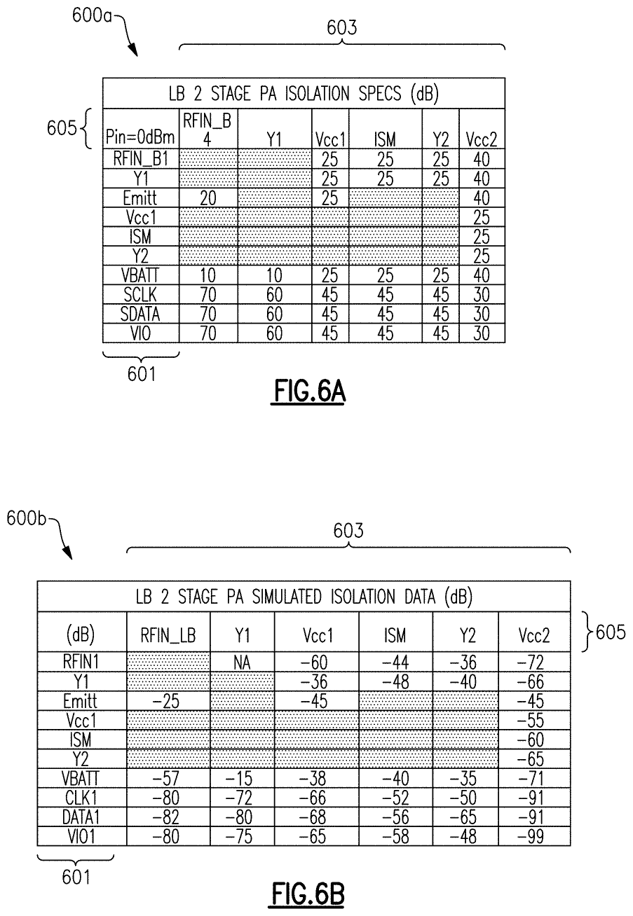

FIG. 5 is a schematic of a low band two stage power amplifier 500. RFIN represents the signal input to the two stage power amplifier 500. Y1 is input into the first stage 501 of the two stage power amplifier 500. The output signal from the first stage 501 of the two stage power amplifier is represented by Emitt. Vcc1 is the common collector voltage of the first stage amplifier 501. Y2 is input into the second stage 503 of the two stage power amplifier 500, and finally Vcc2 is the common collector voltage of the second stage amplifier 503 of the two stage power amplifier 500.

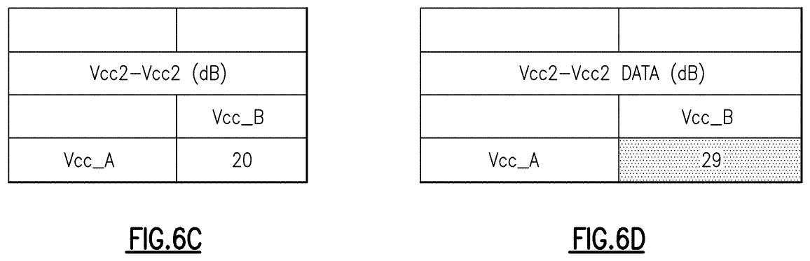

FIG. 6A is a table 600a of the isolation requirements in dB between a first component (column 601) and a second component (row 605) of the two stage power amplifier 500 of FIG. 5. The isolation requirements between the first component and one or more second components are then set out in columns 603. For example, it can be seen that the isolation requirement between RFIN_B1 and Vcc1 is 25 dB whilst the isolation requirement between SCLK and Y1 is 60 dB. FIG. 6B is a corresponding table 600b of the simulated level of isolation between the first and second components. Comparing the equivalent cells in table 600a and table 600b enables a determination as to whether the isolation between the components that correspond to that cell meets the required threshold. For example, comparing the cell corresponding to the isolation between CLK1 and Y1 in table 600b with the corresponding cell in table 600a (SCLK and Y1) shows that the simulated isolation is 71 dB whilst the requirement is for 60 dB of isolation. Accordingly, this isolation requirement is met. Looking at the other cells reveals that in the present example all of the isolation requirements are met, and so it can be deduced that the low band two stage power amplifier meets the required isolation requirements. FIGS. 6A and 6B show a similar relationship between the required Vcc2-Vcc2 isolation (FIG. 6C) and the simulated isolation (FIG. 6D). As can be seen, the simulated isolation is 29 dB, meeting the requirement for 20 dB isolation.

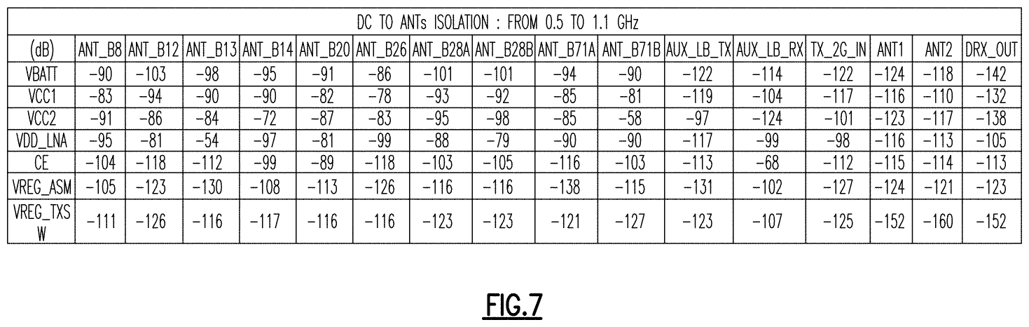

Similar comparisons can be made between other components and signal paths of a multichip module, such as multichip module 100 of FIG. 1 or multichip module 200 of FIG. 2, based on simulated isolation values. FIGS. 7 to 14 illustrate further examples.

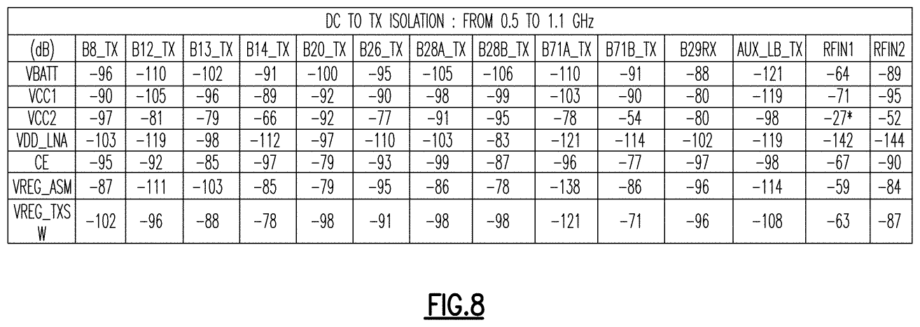

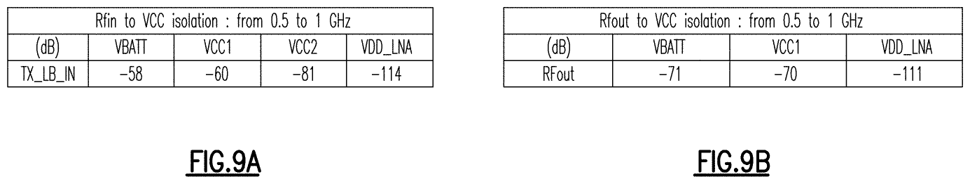

FIG. 7 is a table showing the simulated isolation between various DC components of the multichip module, such as the battery voltage VBATT, and the antennae. FIG. 8 shows the simulated isolation between the DC components and points along the transmit paths of the multichip module. FIGS. 9A and 9B show the isolation between the inputs and outputs of the multichip module respectively and stages of the connected amplifiers. In each case, for FIGS. 7 to 9, the isolation requirement is 30 dB and so in each case this requirement is met by the multichip module being simulated.

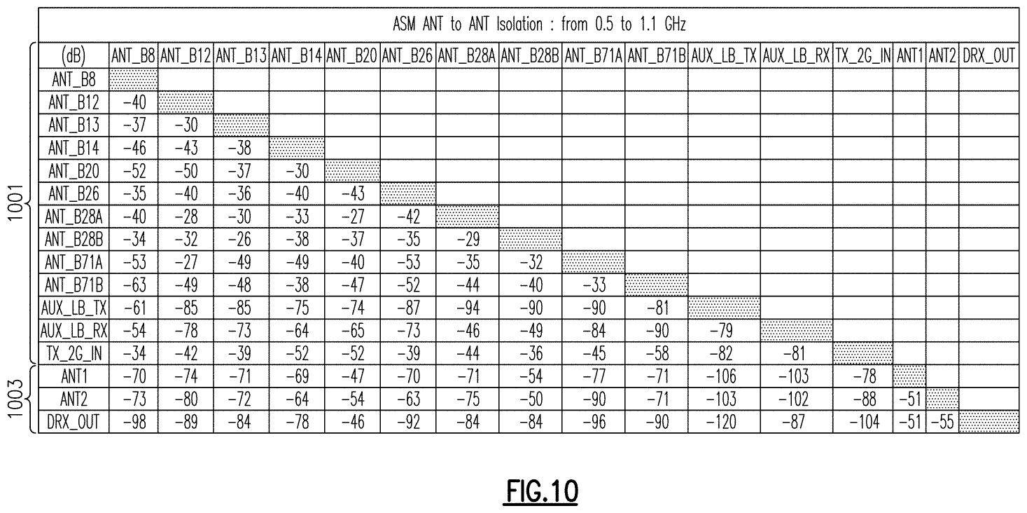

FIG. 10 shows the results of the simulated isolation between components within a sub-module of the multichip module. In this case, the simulated isolation between the antenna connections of the antenna switch module are shown. The isolation requirements between different portions of the sub-module may vary, as in this case where the isolation between the antenna connections ANT1, ANT2 and DRX_OUT (two antennae and a diversity receiver) and different bands, such as ANT_B8 and ANT_B12 is greater (at 45 dB) than between the connections for the simply between the different bands, such as ANT_B8 and ANT_B12 (at 25 dB).

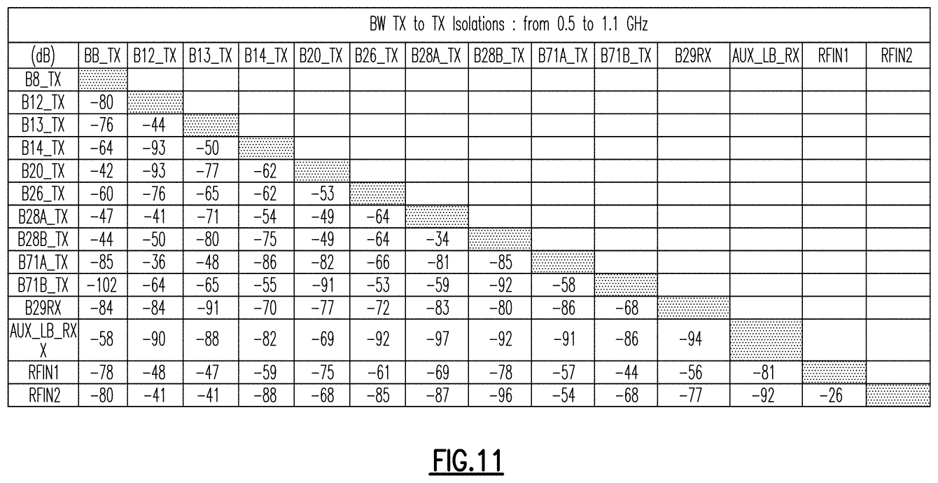

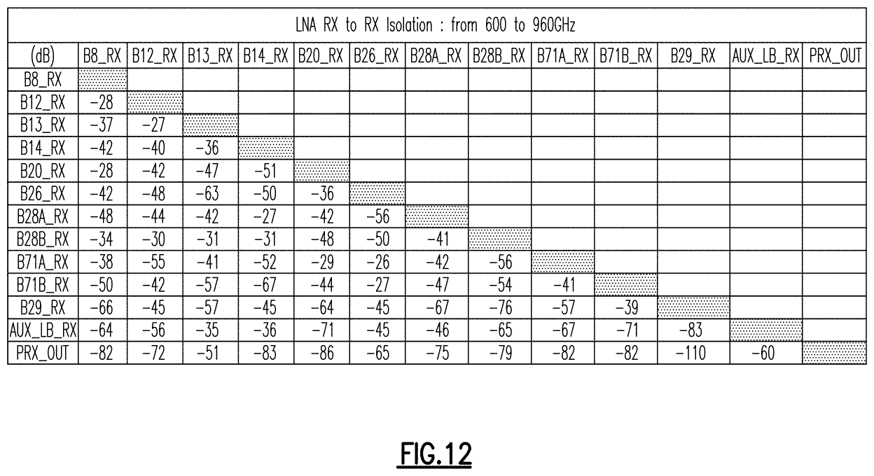

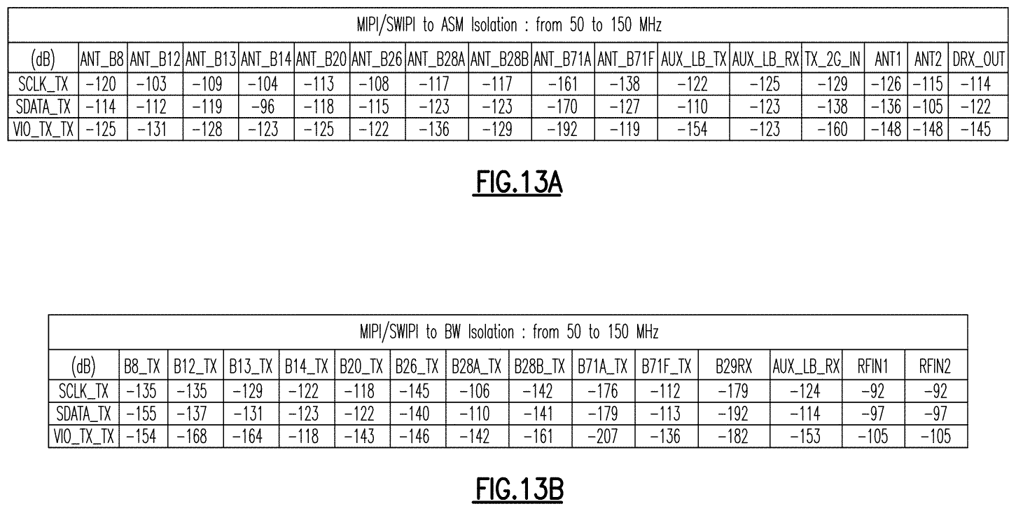

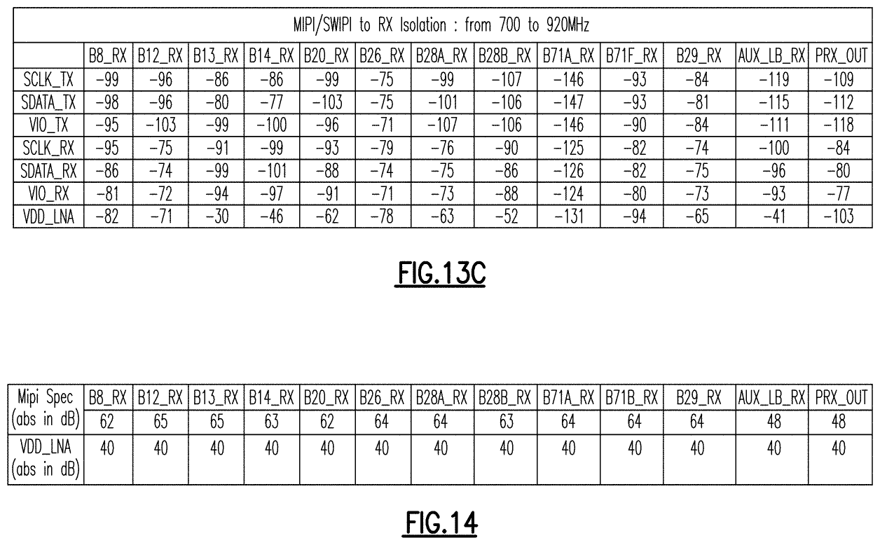

Similarly, FIG. 11 shows the simulated isolation values between different transmit bands, whilst FIG. 12 shows the simulated isolation between the different receive bands as well as the outputs of the low noise amplifier. In FIG. 12, as with FIG. 10, different isolation requirements exist, and it is noted that between receive bands, such as B8_ RX and B12_RX, the isolation requirement is 25 dB whereas between the receive bands and the outputs of the LNA the isolation requirement is 30 dB. FIGS. 13A, 13B and 13C show isolation simulation results for the MIPI/SWIPI with the different bands at the antenna switch module, on the transmit path, and on the receive path respectively. FIG. 14 shows the corresponding isolation requirements.

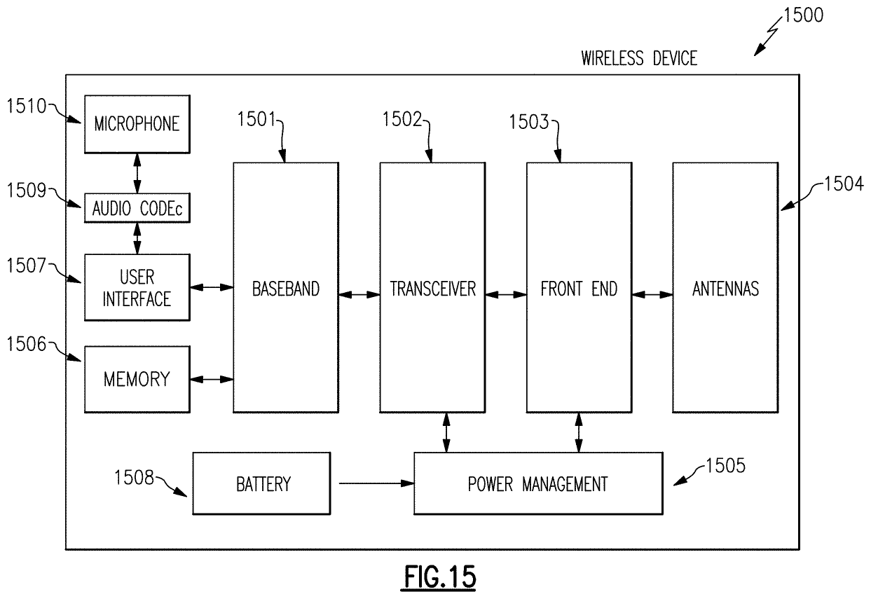

FIG. 15 is a schematic diagram of a wireless device 1500 in accordance with aspects of the invention. The wireless device 1500 can be, for example but not limited to, a wireless access point, such as a router, or a portable telecommunication device, such as a mobile cellular-type telephone. The wireless device 1500 can include a microphone arrangement 1500, and may include one or more of a baseband system 1501, a transceiver 1502, a front end system 1503, one or more antennae 1504, a power management system 1505, a memory 1506, a user interface 1507, a battery 1508, and audio codec 1509. The microphone arrangement may supply signals to the audio codec 1509 which may encode analog audio as digital signals or decode digital signals to analog. The audio codec 1509 may transmit the signals to a user interface 1507. The user interface 1507 transmits signals to the baseband system 1501. The transceiver 1502 generates RF signals for transmission and processes incoming RF signals received from the antennae. The front end system 1503 aids in conditioning signals transmitted to and/or received from the antennae 1504. The antennae 1504 can include antennae used for a wide variety of types of communications. For example, the antennae 1504 can include antennae 1504 for transmitting and/or receiving signals associated with a wide variety of frequencies and communications standards. The baseband system 1501 is coupled to the user interface to facilitate processing of various user input and output, such as voice and data. The baseband system 1501 provides the transceiver 1502 with digital representations of transmit signals, which the transceiver 1502 processes to generate RF signals for transmission. The baseband system 1501 also processes digital representations of received signals provided by the transceiver 1502.

As shown in FIG. 15, the baseband system 1501 is coupled to the memory 1506 to facilitate operation of the wireless device 1500. The memory 1506 can be used for a wide variety of purposes, such as storing data and/or instructions to facilitate the operation of the wireless device 1500 and/or to provide storage of user information. The power management system 1505 provides a number of power management functions of the wireless device 1500. The power management system 1505 receives a battery voltage from the battery 1508. The battery 1508 can be any suitable battery for use in the wireless device, including, for example, a lithium-ion battery. In other cases, however, the battery 1508 may instead be replaced by a mains electricity connection.

The multichip modules described herein in accordance with the present invention and made according to the methods disclosed herein may be incorporated into the wireless device 1500 of FIG. 15, for example as an antenna switch module (ASM) in the front end system 1503.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method of generating a multichip module design, the method comprising:
receiving a multichip module design, the multichip module design comprising a plurality of electrical components and a plurality of signal paths defined between electrical components;
simulating, for each electrical component and signal path, an isolation between that electrical component or signal path and a plurality of other electrical components and signal paths; and
updating the multichip module design based on the simulating.

2. The method of claim 1 further comprising, prior to updating the multichip module design:
comparing each simulated isolation to one or more predetermined isolation thresholds; and
determining, based on the comparing of each simulated isolation to one or more predetermined isolation thresholds, whether the multichip module design meets one or more isolation design criteria; and
updating the multichip module design is further based on whether the multichip module design meets the one or more isolation design criteria.

3. The method of claim 1 wherein the act of receiving a multichip module design includes generating a multichip module design.

4. The method of claim 1 wherein the act of simulating, for each electrical component and signal path, the isolation between that electrical component or signal path and the plurality of other electrical components and signal paths includes:
generating a 3D model of the multichip module design; and
simulating, based on the 3D model and for each electrical component and signal path, the isolation between that component or signal path and the plurality of other electrical components and signal paths.

5. The method of claim 4 wherein the plurality of other electrical components and signal paths includes every other electrical component and signal path of the multichip module design.

6. The method of claim 4 wherein the multichip module design includes a plurality of sub-modules, each sub-module including one or more of the plurality of electrical components and the plurality of signal paths, the plurality of other electrical components and signal paths include every other electrical component and signal path in each sub-module.

7. The method of claim 4 wherein the multichip module design includes a plurality of sub-modules, each sub-module including one or more of the plurality of electrical components and the plurality of signal paths, the plurality of other electrical components and signal paths includes every other electrical component and signal path in a different sub-module.

8. The method of claim 2 wherein updating the multichip module design includes, if it is determined that the multichip module design does not meet the one or more isolation design criteria, updating the multichip module design by adjusting at least one of the plurality of electrical components or plurality of signal paths that did not meet an isolation requirement with respect to another of the plurality of other electrical components or signal paths.

9. The method of claim 8 wherein adjusting at least one of the plurality of electrical components or plurality of signal paths includes moving at least one of the plurality of electrical components or plurality of signal paths that did not meet the isolation requirement with respect to another of the electrical components or signal paths with respect to that other electrical component or signal path.

10. The method of claim 9 wherein the multichip module design includes a plurality of layers, and wherein moving at least one of the plurality of electrical components or plurality of signal paths includes moving at least one of the plurality of electrical components or plurality of signal paths to a different layer.

11. The method of claim 9 wherein the multichip module design includes a plurality of layers, and wherein adjusting at least one of the plurality of electrical components or plurality of signal paths includes introducing a ground layer into the multichip module design between two different layers.

12. The method of claim 8 wherein adjusting at least one of the plurality of electrical components or plurality of signal paths includes rotating at least one of the plurality of electrical components or plurality of signal paths.

13. The method of claim 8 wherein adjusting at least one of the plurality of electrical components or plurality of signal paths includes moving one or more pins of the plurality of electrical components.

14. The method of claim 1 wherein each of the plurality of signal paths is represented by one or more nodes, and the isolation between a signal path and a plurality of the other electrical components and signal paths is simulated by comparing the isolation between each node of the signal path and the plurality of the other electrical components and signal paths.

15. The method of claim 1 wherein the method is performed iteratively, wherein the act of receiving a multichip design module includes receiving an updated multichip module design from a previous iteration of the method.

16. The method of claim 1 wherein simulating, for each electrical component and signal path, the isolation between that electrical component or signal path and the plurality of other electrical components and signal paths, outputs one or more of a table, a graph, and a spreadsheet.

17. The method of claim 2 further comprising manufacturing, if it is determined that the multichip module design does meet the one or more isolation design criteria, a multichip module in accordance with the multichip module design.

18. A multichip module manufactured according to the method of claim 17.

19. A radio-frequency module comprising the multichip module of claim 18.

20. A wireless device comprising the radio-frequency module of claim 19.
